(19) United States
(12) Patent Application Publication
(10) Pub. No.: US 2024/0381661 A1
(43) Pub. Date: Nov. 14, 2024

(54) MEMORY ARRAYS WITH LEAKERS

(71) Applicant: Micron Technology, Inc., Boise, ID (US)

(72) Inventors: Riccardo Pazzocco, Verona (IT); Giorgio Servalli, Fara Gera d'Adda (IT); Marcello Mariani, Milano (IT)

(21) Appl. No.: 18/659,356

(22) Filed: May 9, 2024

Related U.S. Application Data
(60) Provisional application No. 63/465,731, filed on May 11, 2023.

(51) Int. Cl. H10B 53/20; H01L 21/28; H01L 29/51; H01L 29/66; H01L 29/78; H01L 29/786; H10B 51/10; H10B 51/20; H10B 53/10

(52) U.S. Cl. CPC H10B 53/20; H01L 29/40111; H01L 29/516; H01L 29/66742; H01L 29/6684; H01L 29/78391; H01L 29/786; H10B 51/10; H10B 51/20; H10B 53/10

(57) ABSTRACT

A variety of applications can include apparatus having a memory device with ferroelectric capacitors as storage structures in memory cells. A ferroelectric capacitor can have a bottom electrode, a top electrode, and ferroelectric material, where a leaker electrically couples the bottom electrode to the top electrode. Conductive plates can be positioned on and contacting a different set of the memory cells. The plates can be separated from each other along a direction parallel to an access line to the array, without dummy memory cells between the different sets of memory cells at the edges of the plates. A number of different fabrication options can be implemented to realize a memory array with container structures that can have small container spacing without dummy memory cells at the edges of plate cuts. The different fabrication options can be realized by differences in process related to top electrode formation.

### PRIORITY APPLICATION

This application claims the benefit of priority to U.S. Provisional Application Ser. No. 63/465,731, filed May 11, 2023, which is incorporated herein by reference in its entirety.

### FIELD OF THE DISCLOSURE

Embodiments of the disclosure relate generally to electronic devices and, more specifically, to memory devices.

### BACKGROUND

Memory devices are typically provided as internal, semiconductor, integrated circuits (ICs) in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the structure and fabrication of storage units in the memory devices.

### BRIEF DESCRIPTION OF THE DRAWINGS

The drawings, which are not necessarily drawn to scale, illustrate generally, by way of example, but not by way of limitation, various embodiments discussed in the present document.

FIGS. 1A-1B represent structures formed to begin a process for forming ferroelectric capacitors as data storage elements coupled to access transistors using container structures to form the ferroelectric capacitors, according to various embodiments.

FIG. 2 shows a structure 200 after further processing structure 100 of FIGS. 1A-1B, according to various embodiments.

FIGS. 3-5 provide a presentation of a process flow that includes a recession of ferroelectric material formed in the structure of FIG. 2 to allow the contact of a leaker with top electrode and plate under the surface of dielectric that separates container structures, according to various embodiments.

FIGS. 6-8 provide a presentation of another process flow that includes a recession of ferroelectric material formed in the structure of FIG. 2, according to various embodiments.

FIGS. 9-11 provide a presentation of a process flow that includes a recession of ferroelectric material formed in the structure of FIG. 2, according to various embodiments.

FIGS. 12A-12B show a non-limiting representation of a memory device having a memory array with leakers, according to various embodiments.

FIG. 13 is a flow diagram of features of an example method of forming a memory cell, according to various embodiments.

FIG. 14 is a flow diagram of features of an example method of forming components of a memory device, according to various embodiments.

FIG. 15 is a flow diagram of features of an example method of forming components of a memory device, according to various embodiments.

FIG. 16 is a schematic of an example memory device that can include an architecture having a memory array, where a memory cell includes a ferroelectric capacitor arranged as a storage unit of the memory cell of a memory device, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In memory devices having memory cells that use capacitors or capacitor-like structures as storage elements, a memory cell can include a capacitor as a storage element with the capacitor having an electrode coupled to a transistor and another electrode coupled to a conductive plate coupled to a reference line, referred to herein as a plate line (PL). The transistor of the memory cell can be a switching unit to the capacitor, with the transistor coupled to an access line (WL), for example a word line, and coupled to a digit line (DL), for example a bit line. A PL can couple the respective plate to a reference, such as system supply voltage (VSS), or to a plate line voltage (VPL) for a memory cell sense operation. In a ferroelectric RAM (FeRAM), a ferroelectric capacitor in each memory can be used as a storage device. A FeRAM, as a non-volatile memory, can maintain a stored logic state for extended periods of time even in the absence of an external power source. DRAMs, which use capacitors as storage elements, are volatile memories that can lose their stored state over time unless the DRAMS are periodically refreshed by an external power source.

A FeRAM can use similar device architectures as a volatile memory, such as a DRAM architecture, but have non-volatile properties due to the use of a ferroelectric capacitor as a storage device. A ferroelectric memory cell can include a capacitor with a ferroelectric material as the insulating material, where the ferroelectric material has non-linear polarization properties, which are characterized by a spontaneous electric polarization that includes a voltage hysteresis. A ferroelectric material maintains a non-zero electric polarization in the absence of an electric field such that different levels of charge of a ferroelectric capacitor can represent different logic states. A ferroelectric memory cell can be written by applying a voltage across the ferroelectric capacitor. Due to the ferroelectric material between the plates of the capacitor of the ferroelectric memory cell, activation of the ferroelectric memory cell can be made in a two-sequence operation of sensing and precharge. Biasing the PL can result in a voltage difference across capacitor, which voltage difference is the difference between the voltage on the plate, coupled to the PL, and the voltage on the DL. In the sensing operation, the voltage on the PL can be raised followed by raising the voltage on the access line to the selected ferroelectric memory cell, where the voltage can be lowered back during the sensing operation while maintaining the voltage of the access line. During the precharge, with the PL maintained in the base line state and the access line maintained in the selected state, the voltage on the DL can be set to the logic state. The voltage on the DL can be lowered prior to removal of the select voltage on the access line.

The memory cells can be arranged in a memory array arranged as subarrays, where the plates of capacitors in each subarray are coupled to a plate for the subarray. Whenever voltage of a plate to a memory cell moves, such as to a higher level from a lower level or to the lower level from the higher level, the voltage of the DL corresponding to the plate should follow the movement of the voltage on the plate to avoid a disturb voltage across memory cells on a selected WL and unselected DL. A disturb voltage to a memory cell is a voltage to which the memory cell is exposed, when nearby memory cells are accessed, that can affect data stored in the memory cell.

Architectures for FeRAMs can include memory cells with each memory cell having an access transistor and a ferroelectric capacitor as a storage component arranged with the ferroelectric capacitor on and extending vertically from the access transistor. The ferroelectric capacitor can be structured with a bottom electrode, a top electrode, and ferroelectric material, with the bottom electrode physically closest to the access transistor.

To reduce capacitances between conductive lines and improve the minimum time interval between successive active commands to the same memory location ((RC), small plates can be used with the array of memory cells. The memory cells can be formed in container structures with container spacing smaller or equal than twelve nanometers. In fabrication, implementation of multiple small plates, which are to be separated by a relatively small distance, can be facilitated by frequent plate cuts in the array, resulting in a significant number of cuts. In conventional approaches with such a small container spacing, dummy cells can be placed at each plate cut to compensate for any small mask misalignment, which would otherwise prevent full electrical contact between a leaker and a top electrode of a ferroelectric capacitor. The lack of full electrical contact can lead to a relatively high disturb risk. A dummy cell is a cell positioned at the level of memory cells and having the structure of a memory cell without a contact to operate as a data storage cell. A leaker is a structure electrically coupling the bottom electrode to the top electrode coupled to a plate of the ferroelectric capacitor to discharge at least a portion of excess charge from the bottom electrode to the plate. However, dummy cells at each plate cut decreases the array density.

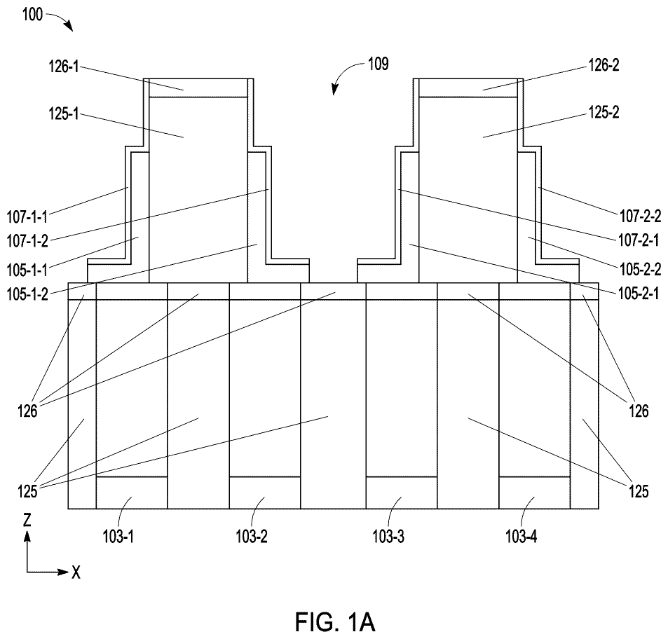

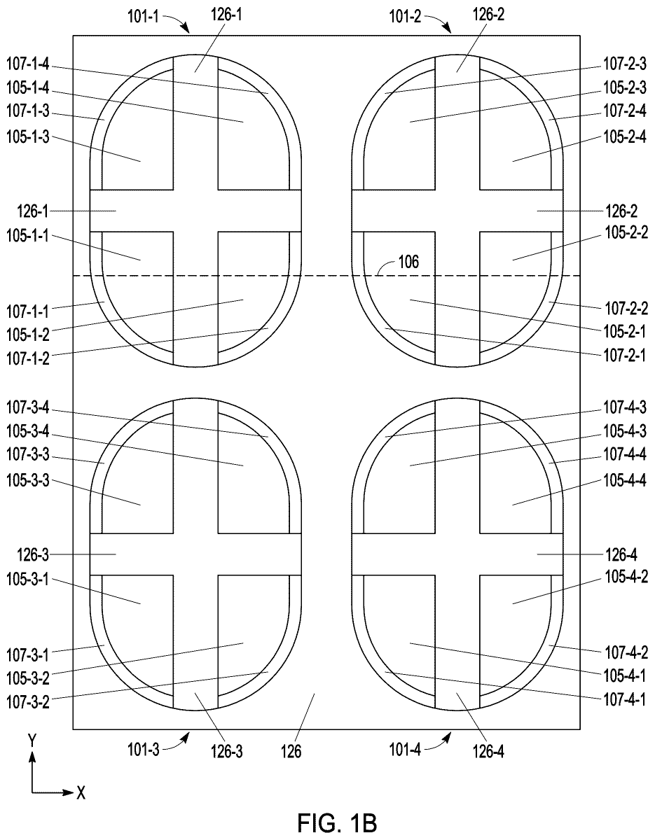

In various embodiments, memory cell functionality with implementation of a fully functional leaker can be preserved at a plate cut edge using procedures that can avoid the use of dummy cells at plate cut edges. FIG. 1A-1B represent structures formed to a begin a process for forming ferroelectric capacitors as data storage elements coupled to access transistors using container structures to form the ferroelectric capacitors. FIG. 1A is a cross-sectional view of a structure 100, along direction 106 in containers shown in FIG. 1B, formed in the middle of a pillar section of access transistors. Structure 100 shows access transistors 103-1, 103-2, 103-3, and 103-4 positioned in dielectric regions 125 and 126 with bottom electrodes of dielectric capacitors, to be formed, positioned on and extending vertically (2-direction) from these access transistors. A bottom electrode 105-1-1 has been formed on transistor 103-1 and formed vertically on one side of a container dielectric having a top region 126-1 on a bottom region 125-1. A leaker 107-1-1 has been formed on bottom electrode 105-1-1, vertically on bottom region 125-1, and vertically on top region 126-1. A bottom electrode 105-1-2 has been formed on transistor 103-2 and formed vertically on another side of the container dielectric having top region 126-1 on bottom region 125-1. A leaker 107-1-2 has been formed on bottom electrode 105-1-2, vertically on bottom region 125-1, and vertically on top region 126-1. A bottom electrode 105-2-1 has been formed on transistor 103-3 and formed vertically on one side of a container dielectric having a top region 126-2 on a bottom region 125-2. A leaker 107-2-1 has been formed on bottom electrode 105-2-1, vertically on bottom region 125-2, and vertically on top region 126-2. A bottom electrode 105-2-2 has been formed on transistor 103-4 and formed vertically on another side of the container dielectric having top region 126-2 on bottom region 125-2. A leaker 107-2-2 has been formed on bottom electrode 105-2-2, vertically on bottom region 125-2, and vertically on top region 126-2.

FIG. 1A shows a small number of memory cells that can be formed in fabrication of a FeRAM device, for ease of presentation. Access transistors 103-1, 103-2, 103-3, and 103-4 can be, but are not limited to, thin film transistors (TFTs). The TFTs can be, but are not limited to, silicon-based TFTs. Top regions 126-1 and 126-2 of the container dielectrics can be, but are not limited to, silicon nitride, and bottom regions 125-1 and 125-2 of the container dielectrics can be, but are not limited to, an insulating oxide. Bottom electrodes 105-1-1, 105-1-2, 105-2-1, and 105-2-2 can be constructed using conductive materials for bottom electrodes of ferroelectric capacitors, such as, but not limited to, one or more of titanium, titanium nitride, tungsten, tungsten nitride, or combinations thereof. Leakers 107-1-1, 107-1-2, 107-2-1, and 107-2-2 can be formed using relatively high resistance conductive material.

Structure 100 has been formed with bottom electrode 105-1-2 separated from bottom electrode 105-2-1 by a separation gap 109. Separation gap 109 can have been performed as a removal of bottom electrode material. An appropriate removal process can use atomic layer etching (ALE). Material for top regions 126-1 and 126-2 of container dielectrics can be formed over bottom regions 125-1 and 125-2 as additional dielectric layers (e.g. silicon nitride) deposited over main container dielectrics (e.g. an oxide) before etching containers to provide selectivity during a subsequent ferroelectric etchback. The overall container dielectric, such as oxide plus silicon nitride, can be implemented to be thicker, such as by approximately 100 nanometers or other appropriate additional thickness, than a conventional container process. The depth of the recess to separate adjacent bottom electrodes can be selected to meet a design leaker resistivity. For example, the bottom electrode recess can be deeper than approximately 100 nanometers or other appropriate additional thickness, as compared to a conventional flow process.

FIG. 1B is a planar view of the top of four container structures 101-1, 101-2, 101-3, and 101-4 after ALE has been performed on the four containers. In this example, each of the four container structures 101-1, 101-2, 101-3, and 101-4 are being processed to form four ferroelectric capacitors of four memory cells. In other embodiments, container structures can be processed to form two ferroelectric capacitors of two memory cells. Container structures 101-1, 101-2, 101-3, and 101-4 can be formed with a dielectric 126, which can be, but is not limited to, silicon nitride. Container structure 101-1 includes bottom electrode 105-1-1 and leaker 107-1-1 for a first memory cell and bottom electrode 105-1-2 and leaker 107-1-2 for a second memory cell, along with top region 126-1 of the container dielectric for container structure 101-1, from FIG. 1A. Container structure 101-1 also includes bottom electrode 105-1-3 and leaker 107-1-3 for a third memory cell and bottom electrode 105-1-4 and leaker 107-1-4 for a fourth memory cell.

Container structure 101-2 includes bottom electrode 105-2-1 and leaker 107-2-1 for a first memory cell and bottom electrode 105-2-2 and leaker 107-2-2 for a second memory cell, along with top region 126-2 of the container dielectric for container structure 101-2, from FIG. 1A. Container structure 101-2 also includes bottom electrode 105-2-3 and leaker 107-2-3 for a third memory cell and bottom electrode 105-2-4 and leaker 107-2-4 for a fourth memory cell.

Container structure 101-3 includes bottom electrode 105-3-1 and leaker 107-3-1 for a first memory cell and bottom electrode 105-3-2 and leaker 107-3-2 for a second memory cell, along with top region 126-3 of the container dielectric for container structure 101-3. Container structure 101-3 also includes bottom electrode 105-3-3 and leaker 107-3-3 for a third memory cell and bottom electrode 105-3-4 and leaker 107-3-4 for a fourth memory cell.

Container structure 101-4 includes bottom electrode 105-4-1 and leaker 107-4-1 for a first memory cell and bottom electrode 105-4-2 and leaker 107-4-2 for a second memory cell, along with top region 126-4 of the container dielectric for container structure 101-4. Container structure 101-4 also includes bottom electrode 105-4-3 and leaker 107-4-3 for a third memory cell and bottom electrode 105-4-4 and leaker 107-4-4 for a fourth memory cell.

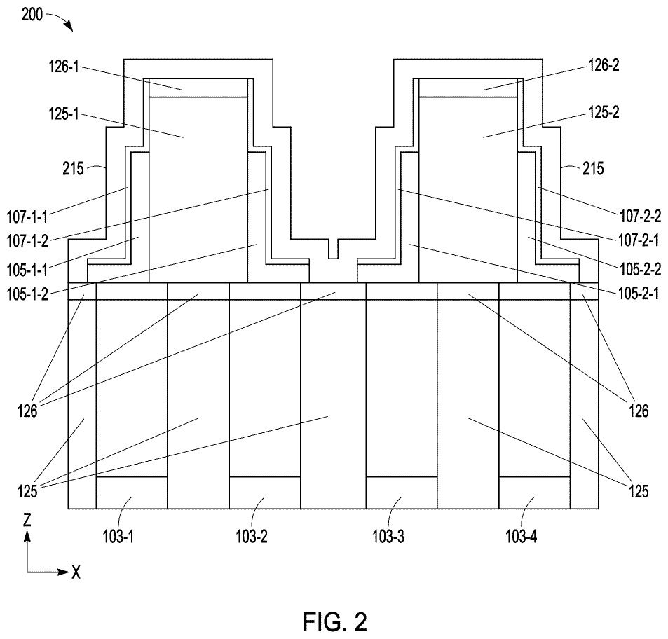

FIG. 2 shows a structure 200 after further processing structure 100 of FIGS. 1A-1B. Ferroelectric material 215 has been formed over the top surfaces of the exposed components of structure 100. Ferroelectric material 215 can include hafnium oxide, zirconium oxide, a combination of hafnium oxide and zirconium oxide, or other appropriate ferroelectric material for a ferroelectric capacitor.

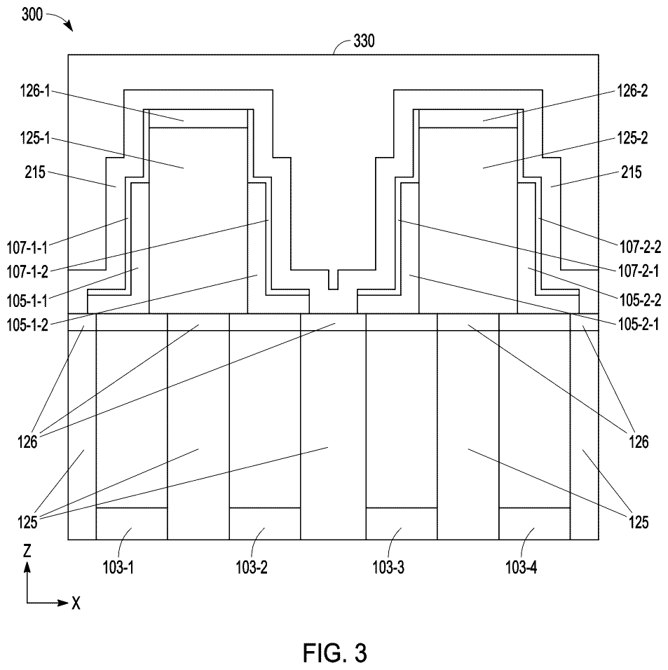

FIGS. 3-5 provide a presentation of a process flow that includes a recession of ferroelectric material 215 formed in structure 200 of FIG. 2 to allow the contact of a leaker with top electrode and plate under the surface of dielectric which separates container structures. FIG. 3 shows a structure 300 after further processing structure 200 of FIG. 2. A resist 330 has been formed over ferroelectric material 215 of structure 200 of FIG. 2. A resist material appropriate for processing ferroelectric material 215 can be used.

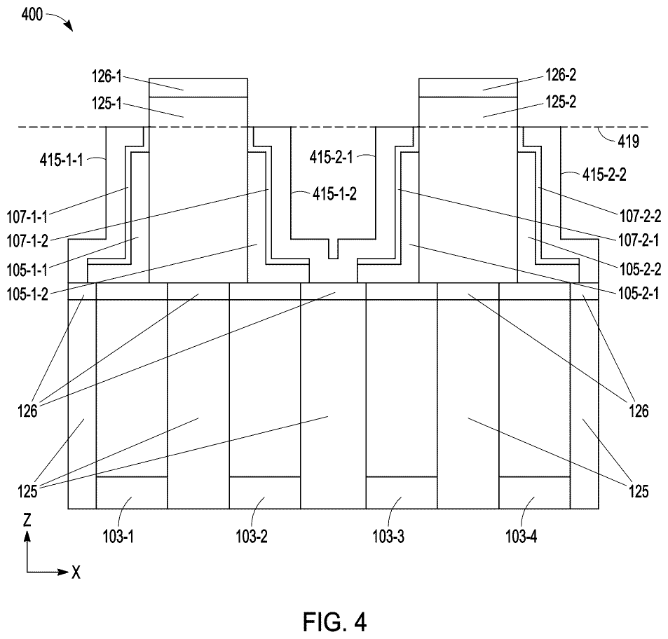

FIG. 4 shows a structure 400 after further processing structure 300 of FIG. 3. Resist 330 has been removed. Leakers 107-1-1 and 107-1-2 and leakers 107-2-1 and 107-2-2 have been removed from surfaces of top region 126-1 and bottom region 125-1 and from surfaces of top region 126-2 and bottom region 125-2, respectively, above a level 419. Level 419 is below top regions 126-1 and 126-2. In some instances, complete removal of leakers 107-1-1, 107-1-2, 107-2-1, and 107-2-2 from these surfaces is not performed since the ferroelectric capacitor of the memory cell can work with or without a residual leaker layer on the sides of top regions 126-1 and 126-2 and bottom regions 125-1 and 125-2 of the dielectric containers above level 419.

Ferroelectric material 215 of structure 200 of FIG. 2 has been removed above level 419. The removal of these portions of ferroelectric material 215 forms ferroelectric material for the ferroelectric capacitors being formed. Removal of ferroelectric material 215 has resulted in ferroelectric material 415-1-1 positioned on bottom electrode 105-1-1 and leaker 107-1-1. Removal of ferroelectric material 215 has also resulted in ferroelectric material 415-1-2 positioned on bottom electrode 105-1-2 and leaker 107-1-2. Removal of ferroelectric material 215 has also resulted in ferroelectric material 415-2-1 positioned on bottom electrode 105-2-1 and leaker 107-2-1. Removal of ferroelectric material 215 has also resulted in ferroelectric material 415-2-2 positioned on bottom electrode 105-2-2 and leaker 107-2-2. Etchback of resist 330 and ferroelectric material 215 provides room for top electrodes and allows metallic contact of the top electrodes with the leaker under the surface of dielectric separating container structures. The ferroelectric material etchback process can define leaker height and leaker resistance.

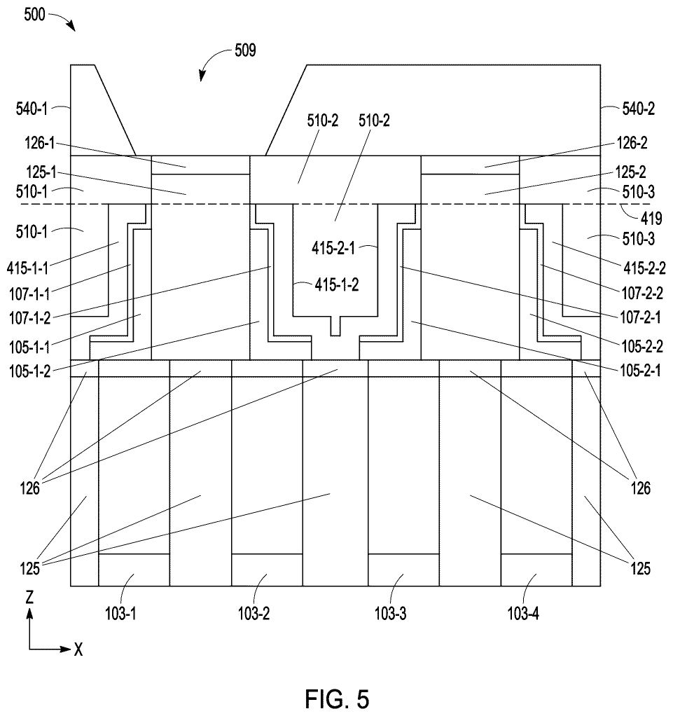

FIG. 5 shows a structure 500 after further processing structure 400 of FIG. 4. A top electrode 510-1 has been formed on ferroelectric material 415-1-1 and on a top surface of leaker 107-1-1 at level 419 of structure 400 of FIG. 4, where the top surface of leaker 107-1-1 was exposed for further processing by the etchback process of FIG. 4. A top electrode 510-2 has been formed on ferroelectric material 415-1-2 and on a top surface of leaker 107-1-2 and on ferroelectric material 415-2-1 and on a top surface of leaker 107-2-1, at level 419 of structure 400 of FIG. 4, where the top surfaces of leakers 107-1-2 and 107-2-1 were exposed for further processing by the etchback process of FIG. 4. A top electrode 510-3 has been formed on ferroelectric material 415-2-2 and on a top surface of leaker 107-2-2 at level 419 of structure 400 of FIG. 4, where the top surface of leaker 107-2-2 was exposed for further processing by the etchback process of FIG. 4. The deposition of the top electrodes provides for the top electrodes of the ferroelectric capacitors being formed to be in contact with their respective leakers, below top regions 126-1 and 126-2 of container dielectrics. The top electrodes 510-1, 510-2, and 510-3 have been planarization.

Processing to form structure 500 has included formation of a common plate on top surfaces of top electrode 510-1, top region 126-1, top electrode 510-2, top region 126-2, and top electrode 510-3. The common plate deposited has been subjected to a plate cut forming plate 540-1 and plate 540-2 separated by opening 509. Ferroelectric capacitors of memory cells at plate cut edges will have a full leaker contacting top electrodes, since the contact is buried below top regions 126-1 and 126-2 of a container dielectric. The spacing of opening 509 above top region 126-1 can allow the plate cut to be larger than spacing between container structures and some misalignment of the plates can be tolerable.

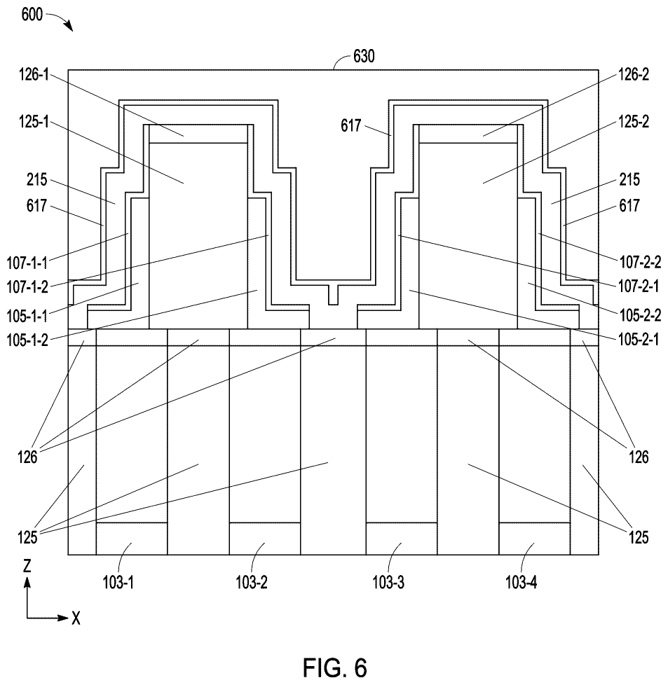

FIGS. 6-8 provide a presentation of a process flow that includes a recession of ferroelectric material 215 formed in structure 200 of FIG. 2 to allow the contact of a leaker with top electrode and plate under the surface of dielectric which separates container structures. FIG. 6 shows a structure 600 after further processing structure 200 of FIG. 2. A relatively thin metallic layer 617 has been formed on ferroelectric material 215 and a resist 630 has been formed on metallic layer 617. During subsequent etch back, the surface of ferroelectric material 215 can be affected by damage phenomena such as creation of dangling bonds and superficial traps. Moreover, the ions involved in the etch process can contaminate the ferroelectric surface and affect its fundamental interaction with the top electrode material to be formed. Metallic layer 617 can be implemented to protect the active surface of ferroelectric material 215 from interaction with resist 630 and subsequent resist stripping. A resist material appropriate for processing ferroelectric material 215 and metallic layer 617 can be used. The deposition of metallic layer 617 can be considered deposition of what will become second top electrodes for the ferroelectric capacitors being formed.

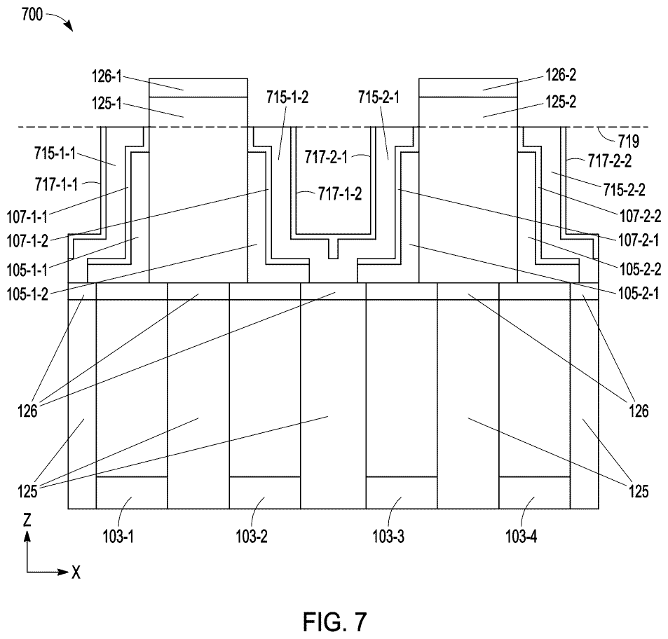

FIG. 7 shows a structure 700 after further processing structure 600 of FIG. 6. Resist 630 has been removed. Leakers 107-1-1 and 107-1-2 and leakers 107-2-1 and 107-2-2 have been removed from surfaces of top region 126-1 and bottom region 125-1 and from surfaces of top region 126-2 and bottom region 125-2, respectively, above a level 719. Level 719 is below top regions 126-1 and 126-2. In some instances, complete removal of leakers 107-1-1, 107-1-2, 107-2-1, and 107-2-2 from these surfaces is not performed since the ferroelectric capacitor of the memory cell can work with or without a residual leaker layer on the sides of top regions 126-1 and 126-2 and bottom regions 125-1 and 125-2 of the dielectric containers above level 719.

Ferroelectric material 215 of structure 200 of FIG. 2 has been removed above level 719. The removal of these portions of ferroelectric material 215 forms ferroelectric material for the ferroelectric capacitors being formed. Removal of ferroelectric material 215 has resulted in ferroelectric material 715-1-1 positioned on bottom electrode 105-1-1 and leaker 107-1-1. Removal of ferroelectric material 215 has also resulted in ferroelectric material 715-1-2 positioned on bottom electrode 105-1-2 and leaker 107-1-2. Removal of ferroelectric material 215 has also resulted in ferroelectric material 715-2-1 positioned on bottom electrode 105-2-1 and leaker 107-2-1. Removal of ferroelectric material 215 has also resulted in ferroelectric material 715-2-2 positioned on bottom electrode 105-2-2 and leaker 107-2-2.

Metallic layer 617 of structure 600 of FIG. 6 has been removed above level 719. Partial removal of metallic layer 617 has resulted in metal layer 717-1-1 positioned on ferroelectric material 715-1-1, exposing top surfaces of metal layer 717-1-1 and ferroelectric material 715-1-1 at level 719 below top region 126-1. Partial removal of metallic layer 617 has resulted in metal layer 717-1-2 positioned on ferroelectric material 715-1-2, exposing top surfaces of metal layer 717-1-2 and ferroelectric material 715-1-2 at level 719 below top region 126-1. Partial removal of metallic layer 617 has resulted in metal layer 717-2-1 positioned on ferroelectric material 715-2-1, exposing top surfaces of metal layer 717-2-1 and ferroelectric material 715-2-1 at level 719 below top region 126-2. Metal layer 717-1-2 can run to and be connected to metal layer 717-2-1. Partial removal of metallic layer 617 has resulted in metal layer 717-2-2 positioned on ferroelectric material 715-2-2, exposing top surfaces of metal layer 717-2-2 and ferroelectric material 715-2-2 at level 719 below top region 126-1.

Etchback of resist 630, metal layer 617, and ferroelectric material 215 provides room for top electrodes and allows metallic contact of the top electrodes with the leaker under the surface of dielectric separating container structures. The ferroelectric material etchback process can define leaker height and leaker resistance.

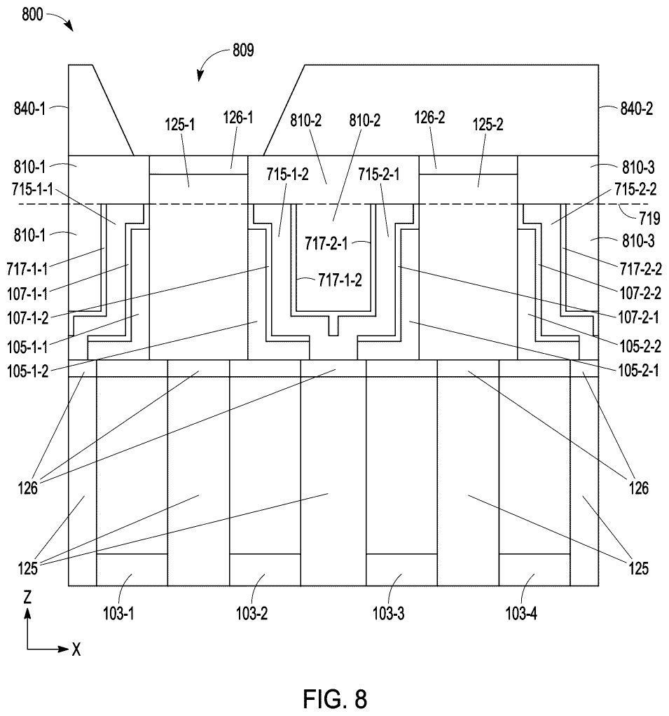

FIG. 8 shows a structure 800 after further processing structure 700 of FIG. 7. A top electrode 810-1 has been formed on ferroelectric material 715-1-1 and on a top surface of leaker 107-1-1 at level 719 of structure 700 of FIG. 7, where the top surface of leaker 107-1-1 was exposed for further processing by the etchback process of FIG. 7. A top electrode 810-2 has been formed on ferroelectric material 715-1-2 and on a top surface of leaker 107-1-2 and on ferroelectric material 715-2-1 and on a top surface of leaker 107-2-1, at level 719 of structure 700 of FIG. 7, where the top surfaces of leakers 107-1-2 and 107-2-1 were exposed for further processing by the etchback process of FIG. 7. A top electrode 810-3 has been formed on ferroelectric material 715-2-2 and on a top surface of leaker 107-2-2 at level 719 of structure 700 of FIG. 7, where the top surface of leaker 107-2-2 was exposed for further processing by the etchback process of FIG. 7. The deposition of the top electrodes provides for the top electrodes of the ferroelectric capacitors being formed to be in contact with their respective leakers, below top regions 126-1 and 126-2 of container dielectrics. The top electrodes 810-1, 810-2, and 810-3 have been planarized.

Processing to form structure 800 has included formation of a common plate on top surfaces of top electrode 810-1, top region 126-1, top electrode 810-2, top region 126-2, and top electrode 810-3. The common plate deposited has been subjected to a plate cut, forming plate 840-1 and plate 840-2 separated by opening 809. Ferroelectric capacitors of memory cells at plate cut edges will have a full leaker contacting top electrodes, since the contact is buried below top regions 126-1 and 126-2 of container dielectric. The spacing of opening 809 above top region 126-1 can allow the plate cut to be larger than spacing between container structures and some misalignment of the plates can be tolerable.

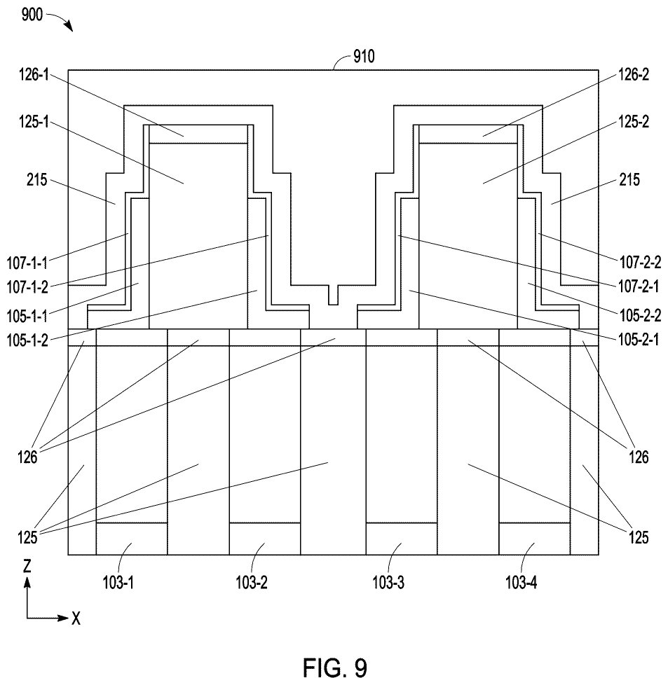

FIGS. 9-11 provide a presentation of a process flow that includes a recession of ferroelectric material 215 formed in structure 200 of FIG. 2 to allow the contact of a leaker with top electrode and plate under the surface of dielectric which separates container structures. FIG. 9 shows a structure 900 after further processing structure 200 of FIG. 2. Top electrode material 910 has been formed on ferroelectric material 215. Full deposition of top electrode material 910 can protect the active surface of ferroelectric material 215 during a following etchback of ferroelectric material 215.

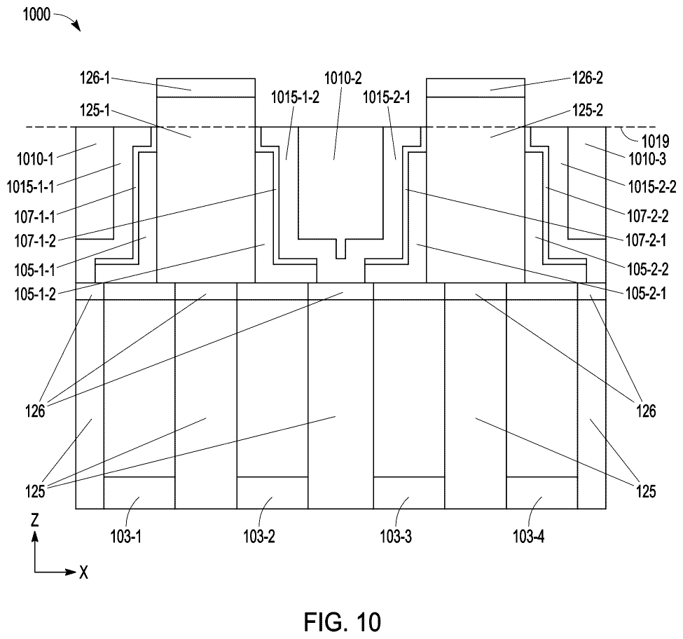

FIG. 10 shows a structure 1000 after further processing structure 900 of FIG. 9. Portions of top electrode material 910 have been removed. Leakers 107-1-1 and 107-1-2 and leakers 107-2-1 and 107-2-2 have been removed from surfaces of top region 126-1 and bottom region 125-1 and from surfaces of top region 126-2 and bottom region 125-2, respectively, above a level 1019. Level 1019 is below top regions 126-1 and 126-2. In some instances, complete removal of leakers 107-1-1, 107-1-2, 107-2-1, and 107-2-2 from these surfaces is not performed since the ferroelectric capacitor of the memory cell can work with or without a residual leaker layer on the sides of top regions 126-1 and 126-2 and bottom regions 125-1 and 125-2 of the dielectric containers above level 1019.

Ferroelectric material 215 of structure 200 of FIG. 2 has been removed above level 1019. The removal of these portions of ferroelectric material 215 forms ferroelectric material for the ferroelectric capacitors being formed. Removal of ferroelectric material 215 has resulted in ferroelectric material 1015-1-1 positioned on bottom electrode 105-1-1 and leaker 107-1-1. Removal of ferroelectric material 215 has also resulted in ferroelectric material 1015-1-2 positioned on bottom electrode 105-1-2 and leaker 107-1-2. Removal of ferroelectric material 215 has also resulted in ferroelectric material 1015-2-1 positioned on bottom electrode 105-2-1 and leaker 107-2-1. Removal of ferroelectric material 215 has also resulted in ferroelectric material 1015-2-2 positioned on bottom electrode 105-2-2 and leaker 107-2-2.

Top electrode material 910 of structure 900 of FIG. 9 has been removed above level 1019. Partial removal of top electrode material 910 has resulted in top electrode 1010-1 positioned on ferroelectric material 1015-1-1, exposing top surfaces of top electrode 1010-1, ferroelectric material 1015-1-1, and leaker 107-1-1 at level 1019 below top region 126-1. Partial removal of top electrode material 910 has resulted in top electrode 1010-2 positioned on ferroelectric material 1015-1-2, exposing top surfaces of top electrode 1010-2, ferroelectric material 1015-1-2, and leaker 107-1-2 at level 1019 below top region 126-1. Partial removal of top electrode material 910 has resulted in top electrode 1010-2 positioned on ferroelectric material 1015-2-1, exposing top surfaces of ferroelectric material 1015-2-1, top electrode 1010-2, and leaker 107-2-1 at level 1019 below top region 126-2. Partial removal of top electrode material 910 has resulted in top electrode 1010-3 positioned on ferroelectric material 1015-2-2, exposing top surfaces of top electrode 1010-3, ferroelectric material 1015-2-2, and leaker 107-2-2 at level 1019 below top region 126-2.

Etchback of top electrode material 910 and ferroelectric material 215 provides room for plate depositions and allows metallic contact of the top electrodes with the leaker under the surface of dielectric separating container structures. The ferroelectric material etchback process can define leaker height and leaker resistance.

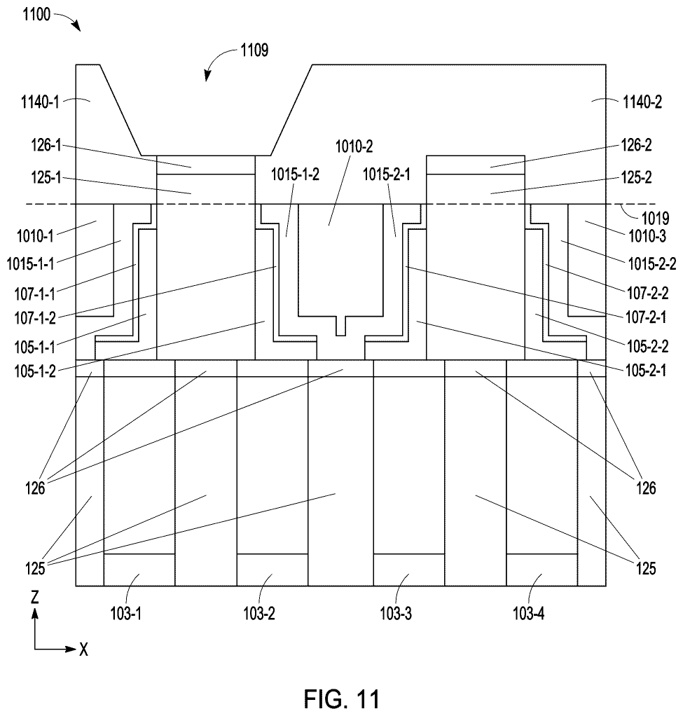

FIG. 11 shows a structure 1100 after further processing structure 1000 of FIG. 10. A common plate has been formed on top surfaces of top electrode 1010-1, ferroelectric material 1015-1-1, leaker 107-1-1, top region 126-1, leaker 107-1-2, ferroelectric material 1015-1-2, top electrode 1010-2, ferroelectric material 1015-2-1, leaker 107-2-1, top region 126-2, leaker 107-2-2, ferroelectric material 1015-2-2, and top electrode 1010-3. A common plate has also been formed on vertical surfaces of top regions 126-1 and 126-2 and bottom regions 125-1 and 125-2. The deposited common plate has been subjected to a plate cut forming plate 1140-1 and plate 1140-2 separated by opening 1109 and region 126-1. Plate 1140-1 and plate 1140-2 will be in contact with the leakers below these plates, under the top of dielectric surface. Ferroelectric capacitors of memory cells at plate cut edges will have a full leaker contacting top electrodes, since the contact is buried below top regions 126-1 and 126-2 of the container dielectric. The spacing of opening 1109 above top region 126-1 can allow the plate cut to be larger than spacing between container structures and some misalignment of the plates can be tolerable.

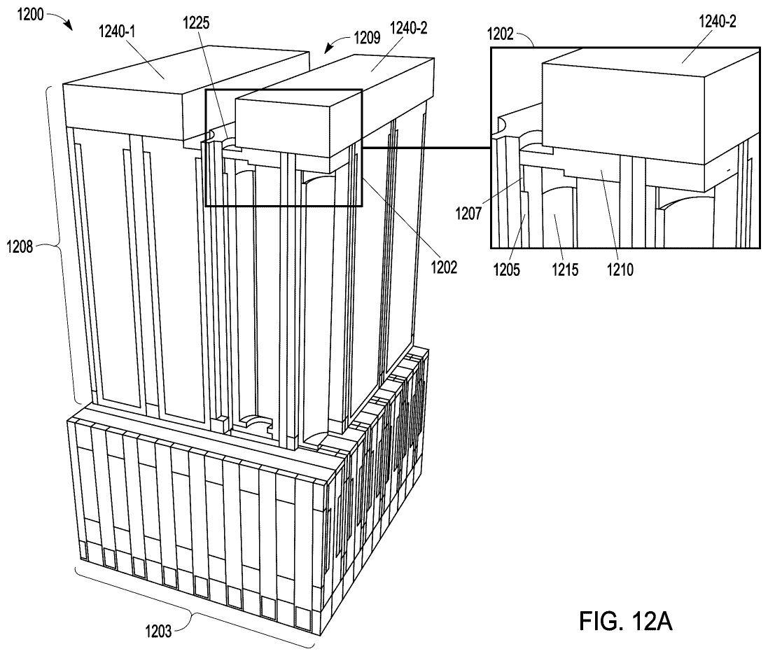

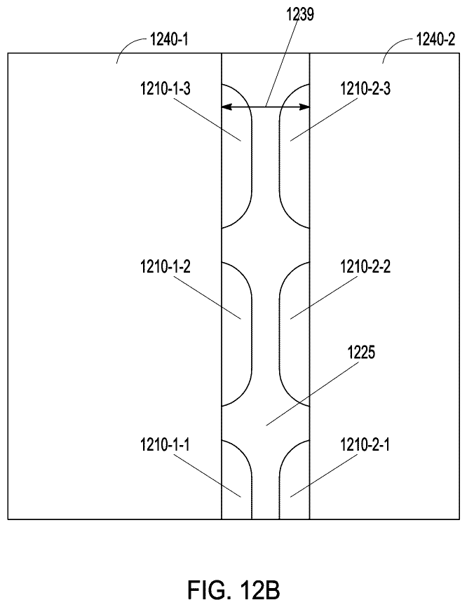

FIGS. 12A-12B show a non-limiting representation of a memory device 1200 having a memory array with leakers. FIG. 12A shows a 3D presentation of memory device 1200 having plate 1240-1 and plate 1240-2 attached to different sets of active memory cells of an array. The array includes a set 1203 of transistors on which set 1208 of ferroelectric capacitors is vertically positioned above the set 1203. Each transistor of set 1203 is coupled to a corresponding ferroelectric capacitor of set 1208. The transistors can be, but are not limited to, TFTs. The ferroelectric capacitors of set 1208 are coupled to plate 1240-1 or plate 1240-2. Plates 1240-1 and 1240-2 are separated from each other by a space 1209 that was generated by cutting a common plate that effectively contained plate 1240-1 and plate 1240-2. Below space 1209 is dielectric container material 1225, which can be made small by any one or combinations of the processes discussed herein, without the use of dummy memory cells to account for misalignment of plates.

Region 1202 shows a region of a ferroelectric capacitor of the set 1208 contacting plate 1240-2. FIG. 12A also shows region 1202 in an expanded view. Plate 1240-2 is on and contacting a top electrode 1210, where top electrode 1210 is on and contacts a leaker 1207 and ferroelectric material 1215. Leaker 1207 also contacts a bottom electrode 1205, where bottom electrode 1205 contacts ferroelectric material 1215, such that ferroelectric material 1215 separates bottom electrode 1205 from top electrode 1210.

FIG. 12B is a top view of plate 1240-1 and plate 1240-2 of FIG. 12A. Plates 1240-1 and 1240-2 are separated from each other by a distance 1239. This top view shows two groups of three ferroelectric capacitors, where a first group is below and contacted by plate 1240-1 and a second group is below and contacted plate 1240-2. The first group includes top electrodes 1210-1-3, 1210-1-2, and 1210-1-1 separated from each other by container dielectric material 1225. The second group includes top electrodes 1210-2-3, 1210-2-2, and 1210-2-1 separated from each other by container dielectric material 1225. The first group and the second group are separated from each other by container dielectric material 1225.

In the process flows discussed above or variations thereof and in completed memory cells having ferroelectric capacitors as storage structures, various materials can be selected to be used in the components of the various structures. Conductive materials for bottom electrodes and top electrodes of ferroelectric capacitors can include, but are not limited to, titanium, titanium nitride, tungsten nitride, or combinations of these materials. Materials for the ferroelectric between the bottom electrodes and top electrodes of ferroelectric capacitors can include, but are not limited to, hafnium oxide, zirconium oxide, or combinations of hafnium oxide and zirconium oxide.

Various deposition techniques for components of structures in the process flows discussed above or similar structures and process flows can be used that are typical for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing. Etching procedures can include, but are not limited to, wet etching, dry etching, and atomic layer etching deposition, among others.

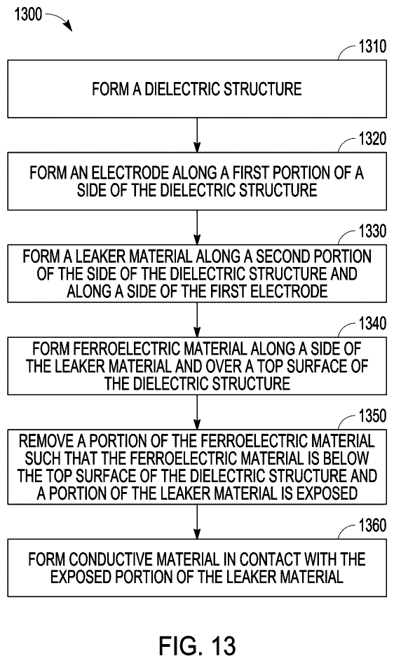

FIG. 13 is a flow diagram of features of an embodiment of an example method 1300 of forming a memory cell. At 1310, a dielectric structure is formed. The dielectric structure can be formed vertically from a substrate that is appropriate for a memory device having the memory cell being fabricated. The dielectric structure can be formed above an access transistor for the memory cell. At 1320, an electrode is formed along a first portion of a side of the dielectric structure. At 1330, a leaker material is formed along a second portion of the side of the dielectric structure and along a side of the first electrode.

At 1340, ferroelectric material is formed along a side of the leaker material and over a top surface of the dielectric structure. At 1350, a portion of the ferroelectric material is removed such that the ferroelectric material is below the top surface of the dielectric structure and a portion of the leaker material is exposed. At 1360, conductive material is formed in contact with the exposed portion of the leaker material.

Variations of method 1300 or methods similar to method 1300 can include a number of different embodiments that may be combined depending on the application of such methods and/or the architecture of systems including a memory cell in which such methods are implemented. Such methods can include forming the dielectric structure by a procedure comprising forming an oxide structure and forming a nitride structure over the oxide structure.

Variations of method 1300 or methods similar to method 1300 can include forming a resist material over the ferroelectric material, and removing a portion of the ferroelectric material can include etching back a portion of the resist material and the portion of the ferroelectric material. Variations can include a portion of the leaker material being etched back. A remaining portion of the resist material can be removed. Variations can include forming conductive material in contact with the exposed portion of the leaker material using procedures including forming top electrode material in contact with the exposed portion of the leaker material after removing the remaining portion of the resist material. Variations can include planarizing the top electrode material, forming plate material over the top electrode material, and cutting the plate material.

Variations of method 1300 or methods similar to method 1300 can include forming a metallic material over the ferroelectric material and forming a resist material over the metallic material, where removing a portion of the ferroelectric material can be precluded with procedures including etching back a portion of the resist material, a portion of the metallic material, and the portion of the ferroelectric material.

Variations of method 1300 or methods similar to method 1300 can include, after forming the ferroelectric material along the side of the leaker material and over the top surface of the dielectric structure, forming a top electrode material over the ferroelectric material. In such a procedure, removing a portion of the ferroelectric material can include etching back the portion of the ferroelectric material and etching back a portion of the top electrode material. In such a procedure, forming conductive material in contact with the exposed portion of the leaker material can include forming plate material in contact with the exposed portion of the leaker material. The plate material can be cut.

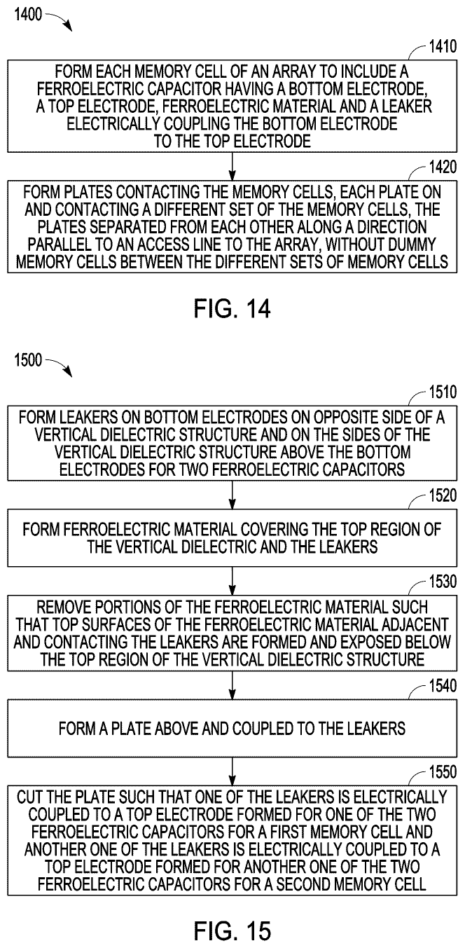

FIG. 14 is a flow diagram of features of an embodiment of an example method 1400 of forming components of a memory device. At 1410, an array of memory cells is formed. Each memory cell includes a ferroelectric capacitor, where each ferroelectric capacitor has a bottom electrode, a top electrode, and ferroelectric material. A leaker electrically couples the bottom electrode to the top electrode. At 1420, plates contacting the memory cells are formed. Each plate is positioned on and contacting a different set of the memory cells. The plates are separated from each other along a direction parallel to an access line to the array, without dummy memory cells between the different sets of memory cells.

Variations of method 1400 or methods similar to method 1400 can include a number of different embodiments that may be combined depending on the application of such methods and/or the architecture of systems including a memory device in which such methods are implemented. Such methods can include forming the bottom electrode and the leaker directly on an adjacent dielectric structure below a top region of the dielectric structure with the leaker on and extending from a top surface of the bottom electrode along the dielectric structure. The ferroelectric material is formed on a vertical side of the leaker. The top electrode is formed contacting the leaker on a top surface of the leaker, below the top region of the dielectric structure. A plate is formed on and contacting the top electrode.

Variations of method 1400 or methods similar to method 1400 can include forming the bottom electrode and the leaker directly on an adjacent dielectric structure below a top region of the dielectric structure with the leaker on and extending from a top surface of the bottom electrode along the dielectric structure. The leaker has a length extending from the top surface of the leaker downward. The ferroelectric material is formed on a vertical side of the leaker. A second top electrode is formed on the ferroelectric material opposite the leaker in a direction along a portion of the length of the leaker. The top electrode is formed contacting the leaker on a top surface of the leaker and positioned on and contacting the second top electrode. A plate is formed on and contacting the top electrode.

Variations of method 1400 or methods similar to method 1400 can include forming the bottom electrode and the leaker directly on an adjacent dielectric structure below a top region of the dielectric structure with the leaker on and extending from a top surface of the bottom electrode along the dielectric structure. The leaker has a top surface and a length extending from the top surface of the leaker downward. The ferroelectric material is formed on a vertical side of the leaker. The top electrode is formed on the ferroelectric material opposite the leaker along a portion of the length of the leaker such that a top surface of the top electrode is at a vertical level of the top surface of the leaker and separated from the top surface of the leaker by a top surface of the ferroelectric material. A plate is formed on and contacting the top surface of the leaker, the top surface of the ferroelectric material, and the top surface of the top electrode. The plate is formed extending from below the top region of the dielectric structure to above the top region of the dielectric structure. Variations can include forming the separated plates by forming a common plate and cutting the common plate above a dielectric structure having a ferroelectric capacitor of a memory cell on one side of the dielectric structure and another ferroelectric capacitor of another memory cell of an opposite side of the dielectric structure.

FIG. 15 is a flow diagram of features of an embodiment of an example method 1400 of forming components of a memory device. At 1510, leakers are formed on bottom electrodes on opposite sides of a vertical dielectric structure and on the sides of the vertical dielectric structure above the bottom electrodes for two ferroelectric capacitors. The vertical dielectric structure has a top region positioned on a bottom region. At 1520, ferroelectric material is formed covering the top region of the vertical dielectric and the leakers. At 1530, portions of the ferroelectric material and the leakers are removed such that top surfaces of the leakers and top surfaces of the ferroelectric material adjacent and contacting the leakers are formed and exposed below the top region of the vertical dielectric structure. At 1540, a plate is formed above and coupled to the leakers. At 1550, the plate is cut such that one of the leakers is electrically coupled to a top electrode formed for one of the two ferroelectric capacitors for a first memory cell and another one of the leakers is electrically coupled to a top electrode formed for another one of the two ferroelectric capacitors for a second memory cell.

Variations of method 1500 or methods similar to method 1500 can include a number of different embodiments that may be combined depending on the application of such methods and/or the architecture of systems including a memory device in which such methods are implemented. Such methods can include forming the top electrode for one of the two ferroelectric capacitors on ferroelectric material for the one of the two ferroelectric capacitors and on a top surface of one of the leakers for the one of the two ferroelectric capacitors. The top electrode can be formed extending from the top surface of the one of the leakers to a top surface of the top region of the vertical dielectric structure.

Variations of method 1500 or methods similar to method 1500 can include, for one of the two ferroelectric capacitors, forming a metallic layer on the ferroelectric material opposite the leaker, with a top surface of the metallic layer at a vertical level of the top surface of the leaker and the top surface of the ferroelectric material. The top electrode can be formed on the metallic layer, on the top surface of the ferroelectric material, and on the top surface of the leaker, where the top electrode extends from the top surface of the leaker to a top surface of the top region of the vertical dielectric structure.

Variations of method 1500 or methods similar to method 1500 can include, for one of the two ferroelectric capacitors, forming the top electrode on the ferroelectric material such that a top surface of the top electrode is at a vertical level of the top surface of the leaker and the top surface of the ferroelectric material. The plate can be formed, prior to cutting the plate, on the top surface of the top electrode, the top surface of the leaker, and the top surface of the ferroelectric material, with the plate extending above a top surface of the top region of the vertical dielectric structure.

Variations of method 1500 or methods similar to method 1500 can include forming the vertical dielectric structure with the top region including a silicon nitride and the bottom region including an oxide. Cutting the plate can include forming an opening above the silicon nitride.

In various embodiments, a memory device can comprise an array of memory cells and plates contacting the memory cells. Each memory cell can include a ferroelectric capacitor, where each ferroelectric capacitor has a bottom electrode, a top electrode, ferroelectric material and a leaker electrically coupling the bottom electrode to the top electrode. Each plate can be positioned on and contacting a different set of the memory cells. The plates can be arranged separated from each other along a direction parallel to an access line to the array, without dummy memory cells between the different sets of memory cells.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the top electrode contacting the leaker on a top surface of the leaker, where the top electrode and the leaker are directly adjacent a dielectric surface. A plate is positioned on and contacting the top electrode.

Variations of such a memory device and its features, as taught herein, can include the top electrode contacting the leaker on a top surface of the leaker, where the top electrode and the leaker are directly adjacent a dielectric surface. A plate is positioned on and contacting the top electrode. The leaker has a length extending from the top surface of the leaker downward, where the leaker is separated from a second top electrode along the length by the ferroelectric material of the ferroelectric capacitor. The second top electrode is positioned between the ferroelectric material and the top electrode of the ferroelectric capacitor.

Variations of such a memory device and its features, as taught herein, can include a plate contacting the leaker on a top surface of the leaker. The plate and the leaker can be directly adjacent a dielectric surface. The plate is positioned on and contacting the top electrode. The leaker is separated from the top electrode by ferroelectric material of the ferroelectric capacitor and coupled to the top electrode by the plate. A portion of the plate can extend vertically above and offset from a top surface of the dielectric surface, where the top surface of the dielectric surface is at a level of a top surface of a lower portion of the plate.

Variations of such a memory device and its features, as taught herein, can include electrode material of the top electrode or the bottom electrode including one or more of titanium, titanium nitride, or tungsten nitride. Variations of such a memory device can include ferroelectric material of the ferroelectric capacitor including hafnium oxide, zirconium oxide, or a combination of hafnium oxide and zirconium oxide. Variations of such a memory device can include each memory cell including a transistor coupled to the bottom electrode, with the ferroelectric capacitor of the memory cell extending vertically from the transistor. The transistor can be a TFT.

In various embodiments, a method of forming a memory device can include forming memory cells having ferroelectric capacitors with leakers electrically coupling the bottom electrode to the top electrode of the ferroelectric capacitors under plates, without dummy memory cells between the different sets of memory cells. Such a method can include forming a vertical dielectric structure having a top region on a bottom region; forming a first bottom electrode for a first ferroelectric capacitor on a first side of the vertical dielectric structure, where the first bottom electrode extends from a top of a first transistor to a first position below the top region of the vertical dielectric structure; and forming a second bottom electrode for a second ferroelectric capacitor on a second side of the vertical dielectric structure opposite the first side, where the second bottom electrode extends from a top of a second transistor to a second position below the top region of the vertical dielectric structure. A first leaker is formed on the first bottom electrode and on the first side of the vertical dielectric structure above the first bottom electrode and a second leaker is formed on the second bottom electrode and on the second side of the vertical dielectric structure above the second bottom electrode. Ferroelectric material can be formed covering the top region of the vertical dielectric structure, the first leaker, and the second leaker. Portions of the ferroelectric material, the first leaker, and the second leaker can be removed such that a top surface of the first leaker and a top of ferroelectric material adjacent and contacting the first leaker are formed and exposed below the top region of the vertical dielectric structure and such that a top surface of the second leaker and a top of ferroelectric material adjacent and contacting the second leaker are formed and exposed below the top region of the vertical dielectric structure. A plate can be formed above and coupled to the first leaker and the second leaker. The plate can be cut such that the first leaker is electrically coupled to a top electrode formed for the first ferroelectric capacitor of a first memory cell and the second leaker is electrically coupled to a top electrode formed for the second ferroelectric capacitor of a second memory cell.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as FeRAM, DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor” means a computational circuit including a group of processors or multi-core devices. Such electronic devices can be implemented with architectures for FeRAMs including ferroelectric capacitors as taught herein or other memory devices using non-ferroelectric capacitors having the architecture for ferroelectric storage capacitors as taught herein.

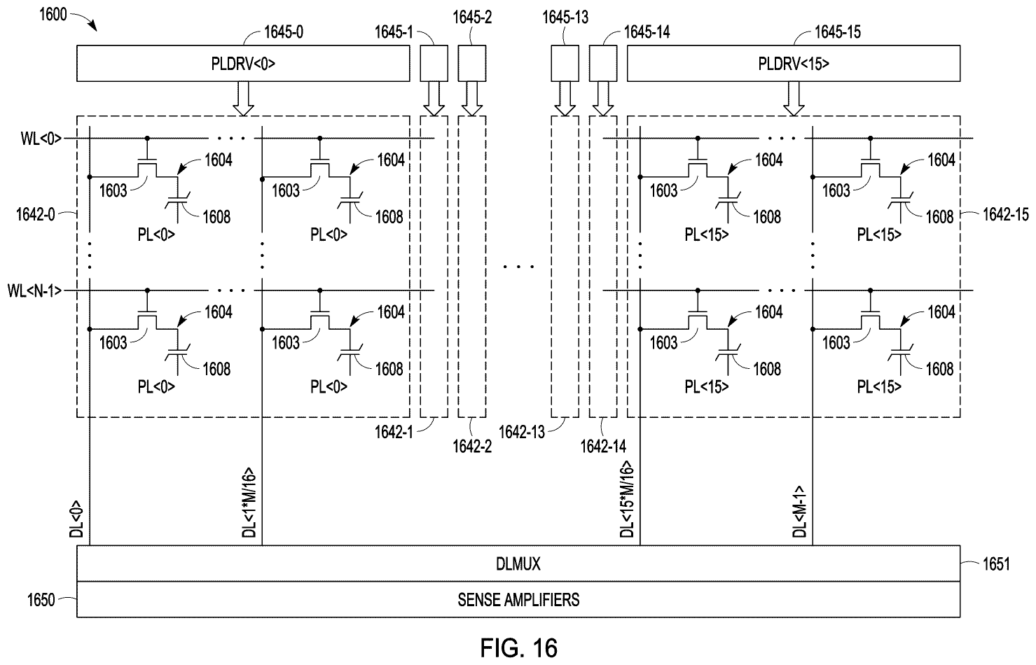

FIG. 16 is a schematic of an embodiment of an example memory device 1600 that can include an architecture having a memory array arranged in subarrays 1642-0, 1642-1, 1642-2 . . . 1642-13, 1642-14, and 1642-15, which can be structured in conjunction with an arrangement of memory cells having ferroelectric capacitor similar to FIG. 5, FIG. 8, FIG. 11, FIGS. 12A-12B, or a combination thereof. Though sixteen subarrays are shown in FIG. 16, memory device 1600 can have more or fewer than sixteen subarrays with an arrangement of plate line selects and plate line drivers adjusted according to the number of subarrays. Memory device 1600 can be, but is not limited to, a FeRAM. Memory device 1600 can be implemented in a variety of electronic devices.

Each subarray of subarrays 1642-0, 1642-1, 1642-2 . . . 1642-13, 1642-14, and 1642-15 of memory device 1600 can include an array of memory cells 1604 (single labels being used to show the components of a memory cell for case of presentation) arranged in rows and columns, where each row is an access line and each column is a DL. Memory device 1600 can include access lines WL<0> . . . . WL<N−1> and digit lines DL<0> . . . . DL<M−1>, where each memory cell is coupled to one access line of access lines WL<0> . . . . WL<N−1> and one digit line of DL<0> . . . . DL<M−1>. Each memory cell 1604 can include a transistor 1603 having a gate coupled to a given access line, a drain/source of transistor 1603 coupled to a given DL, and a drain/source of transistor 1603 coupled to a plate of a capacitor 1608 of memory cell 1604. Capacitor 1608 can be a ferroelectric device with ferroelectric material as the material between two electrode plates. Capacitor 1608 of memory cell 1604 can be structured on and extending vertically from its corresponding transistor 1603 with the associated WL and DL to the transistor 1603 structured at a level with transistor 1603 below the vertical level of capacitor 1608.

Transistor 1603 operates as an access device of memory cell 1604 and capacitor 1608 operates as the data storage component of memory cell 1604, with a plate of capacitor 1608 coupled to a PL<j> assigned to the jth subarray of subarrays 1642-0, 1642-1, 1642-2 . . . 1642-13, 1642-14, and 1642-15 of memory device 1600. In various embodiments, the plate of capacitor 1608 coupled to a PL<j> can be structured as the top plate of capacitor 1608. With each capacitor in a subarray <j> coupled to the same PL<j>, the subarray <j> can be structured with a common plate to the capacitors 1608 of subarray <j>. For simplicity and ease of discussion, the array is shown in only two dimensions, but the array can be extended into the third dimension.

Memory device 1600 includes plate drivers 1645-0, 1645-1, 1645-2 . . . 1645-13, 1645-14, 1645-15. For each N=0, 1, 2 . . . 13, 14, and 15, plate driver 1645-N (PLDRV<N>) is coupled to subarray <N> providing a signal on PL<N> to the plate for subarray <N> to select or unselect the PL<N> for activation of a selected plate of the subarrays.

DLs from each subarray <N> can be coupled to a DL mutliplexer (DLMUX) 1651. DLMUX 1651 can be coupled to sense amplifiers 1650 to read and write to memory cells 1604 of subarrays 1642-0, 1642-1, 1642-2 . . . 1642-13, 1642-14, and 1642-15. The DLs can be grouped with respect to the subarrays. For example, memory cells 1604 of subarray 1642-0 can be coupled to DLs DL<0> . . . . DL<1*M/16> and memory cells 1604 of subarray 1642-15 can be coupled to DLs DL<15*M/16> . . . . DL<M−1>. With M=64, each of subarrays 1642-0, 1642-1, 1642-2 . . . 1642-13, 1642-14, and 1642-16 corresponds to four DLs for each of the sixteen subarrays.

Memory device 1600 can be implemented as an IC within a package that includes pins for receiving supply voltages (e.g., to provide the drain/source and gate voltages for the transistors 1603) and signals (including data, address, and control signals). FIG. 16 depicts memory device 1600 in simplified form to illustrate basic structural components, omitting many details of the memory cells 1604 and associated access lines WL<0> . . . . WL<N−1> and digit lines DL<0> . . . DL<M−1> as well as the peripheral circuitry. For example, memory device 1600 can include further peripheral circuitry, such as a memory control unit that controls the memory operations based on control signals (provided, e.g., by an external processor), additional input/output circuitry, and other appropriate components. Details of such peripheral circuitry are generally known to those of ordinary skill in the art and not further discussed herein.

In two-dimensional (2D) memory arrays, the rows of access lines WL<0> . . . . WL<N−1> and columns of digit lines DL<0> . . . . DL<M−1> of memory cells 1604 are arranged along a single horizontal plane (i.e., a plane parallel to the layers) of the semiconductor substrate, e.g., in a rectangular lattice with mutually perpendicular horizontal WLs and DLs. In 3D memory arrays, the memory cells 1604 can be arranged in a 3D lattice that encompasses multiple vertically stacked horizontal planes corresponding to multiple device tiers of a multi-tier substrate assembly, with each device tier including multiple parallel rows of memory cells 1604 whose transistor gate terminals are connected by horizontal access lines such as access lines WL<0> . . . . WL<N−1>. A “device tier,” as used herein, can include multiple layers (or levels) of materials, but forms the components of memory devices of a single horizontal tier of memory cells. DLs such as digit lines DL<0> . . . . DL<M−1> extend vertically through all or at least a vertical portion of the multi-tier structure, and each of the digit lines DL<0> . . . . DL<M−1> connects to the transistor drain/source terminals of respective vertical columns of associated memory cells 1604 at the multiple device tiers. A 3D configuration of memory cells enables further increases in bit density compared with 2D arrays.

Example embodiments of devices and methods, in accordance with the teachings herein, are described in the following.

An example memory device 1 can comprise an array of memory cells, each memory cell including a ferroelectric capacitor, each ferroelectric capacitor having a bottom electrode, a top electrode, ferroelectric material, and a leaker electrically coupling the bottom electrode to the top electrode; and plates contacting the memory cells, each plate on and contacting a different set of the memory cells, the plates separated from each other along a direction parallel to an access line to the array, without dummy memory cells between the different sets of memory cells.

An example memory device 2 can include features of example memory device 1 and can include the top electrode contacting the leaker on a top surface of the leaker, the top electrode and the leaker being directly adjacent a dielectric surface, with a plate on and contacting the top electrode.

An example memory device 3 can include features of any of the preceding example memory devices and can include the top electrode contacting the leaker on a top surface of the leaker, the top electrode and the leaker directly adjacent a dielectric surface, with a plate on and contacting the top electrode, the leaker having a length extending from the top surface of the leaker downward, the leaker separated from a second top electrode along the length by the ferroelectric material of the ferroelectric capacitor, the second top electrode positioned between the ferroelectric material and the top electrode of the ferroelectric capacitor.

An example memory device 4 can include features of any of the preceding example memory devices and can include a plate contacting the leaker on a top surface of the leaker, the plate and the leaker being directly adjacent a dielectric surface, the plate on and contacting the top electrode, with the leaker separated from the top electrode by ferroelectric material of the ferroelectric capacitor and coupled to the top electrode by the plate.

An example memory device 5 can include features of memory device 4 and any of the preceding example memory devices 1 to 3 and can include a portion of the plate extending vertically above and offset from a top surface of the dielectric surface, the top surface of the dielectric surface being at a level of a top surface of a lower portion of the plate.

An example memory device 6 can include features of example memory device 5 and any of the preceding example memory devices and can include electrode material of the top electrode or the bottom electrode including one or more of titanium, titanium nitride, or tungsten nitride.

An example memory device 7 can include features of example memory device 5 and any of the preceding example memory devices and can include ferroelectric material of the ferroelectric capacitor including hafnium oxide, zirconium oxide, or a combination of hafnium oxide and zirconium oxide.

An example memory device 8 can include features of example memory device 5 and any of the preceding example memory devices and can include each memory cell including a transistor coupled to the bottom electrode, with the ferroelectric capacitor of the memory cell extending vertically from the transistor.

An example memory device 9 can include features of example memory device 8 and any of the preceding example memory devices 1 to 7 and can include the transistor including a TFT.

In an example memory device 10, any of the memory devices of example memory devices 1 to 9 may include memory devices incorporated into an electronic apparatus further comprising a host processor and a communication bus extending between the host processor and the memory device.

In an example memory device 11, any of the memory devices of example memory devices 1 to 10 may be modified to include any structure presented in another of example memory device 1 to 10.

In an example memory device 12, any apparatus associated with the memory devices of example memory devices 1 to 11 may further include a machine-readable storage device configured to store instructions as a physical state, wherein the instructions may be used to perform one or more operations of the apparatus.

In an example memory device 13, any of the memory devices of example memory devices 1 to 12 may be formed or operated in accordance with any of the below example methods 1 to 24.

An example method 1 of forming a memory device can comprise forming an array of memory cells, each memory cell including a ferroelectric capacitor, each ferroelectric capacitor having a bottom electrode, a top electrode, ferroelectric material, and a leaker electrically coupling the bottom electrode to the top electrode; and forming plates contacting the memory cells, each plate on and contacting a different set of the memory cells, the plates separated from each other along a direction parallel to an access line to the array, without dummy memory cells between the different sets of memory cells.

An example method 2 of forming a memory device can include features of example method 1 of forming a memory device and can include forming the bottom electrode and the leaker directly on an adjacent dielectric structure below a top region of the dielectric structure with the leaker on and extending from a top surface of the bottom electrode along the dielectric structure; forming the ferroelectric material on a vertical side of the leaker; forming the top electrode contacting the leaker on a top surface of the leaker, below the top region of the dielectric structure; and forming a plate on and contacting the top electrode.

An example method 3 of forming a memory device can include features of any of the preceding example methods of forming a memory device and can include forming the bottom electrode and the leaker directly on an adjacent dielectric structure below a top region of the dielectric structure with the leaker on and extending from a top surface of the bottom electrode along the dielectric structure, the leaker having a length extending from the top surface of the leaker downward; forming the ferroelectric material on a vertical side of the leaker; forming a second top electrode on the ferroelectric material opposite the leaker along a portion of the length of the leaker; forming the top electrode contacting the leaker on a top surface of the leaker and positioned on and contacting the second top electrode; and forming a plate on and contacting the top electrode.

An example method 4 of forming a memory device can include features of any of the preceding example methods of forming a memory device and can include forming the bottom electrode and the leaker directly on an adjacent dielectric structure below a top region of the dielectric structure with the leaker on and extending from a top surface of the bottom electrode along the dielectric structure, the leaker having a length extending from the top surface of the leaker downward, the leaker having a top surface; forming the ferroelectric material on a vertical side of the leaker; forming the top electrode on the ferroelectric material opposite the leaker along a portion of the length of the leaker such that a top surface of the top electrode is at a vertical level of the top surface of the leaker and separated from the top surface of the leaker by a top surface of the ferroelectric material; and forming a plate on and contacting the top surface of the leaker, the top surface of the ferroelectric material, and the top surface of the top electrode, the plate extending from below the top region of the dielectric structure to above the top region of the dielectric structure.

An example method 5 of forming a memory device can include features of any of the preceding example methods of forming a memory device and can include forming plates separated from each other along a direction parallel to an access line to the array to include forming a common plate and cutting the common plate above a dielectric structure having a ferroelectric capacitor of a memory cell on one side of the dielectric structure and another ferroelectric capacitor of another memory cell of an opposite side of the dielectric structure.

In an example method 6 of forming a memory device, any of the example methods 1 to 5 of forming a memory device may be performed in forming an electronic apparatus further comprising a host processor and a communication bus extending between the host processor and the memory device.

In an example method 7 of forming a memory device, any of the example methods 1 to 6 of forming a memory device may be modified to include operations set forth in any other of example methods 1 to 6 of forming a memory device.

In an example method 8 of forming a memory device, any of the example methods 1 to 7 of forming a memory device may be implemented at least in part through use of instructions stored as a physical state in one or more machine-readable storage devices.

An example method 9 of forming a memory device can include features of any of the preceding example methods 1 to 8 of forming a memory device and can include performing functions associated with any features of example memory devices 1 to 13.

An example method 10 of forming a memory device can comprise forming leakers on bottom electrodes on opposite sides of a vertical dielectric structure and on the sides of the vertical dielectric structure above the bottom electrodes for two ferroelectric capacitors, the vertical dielectric structure having a top region on a bottom region; forming ferroelectric material covering the top region of the vertical dielectric structure and the leakers; removing portions of the ferroelectric material such that top surfaces of the ferroelectric material adjacent and contacting the leakers are formed and exposed below the top region of the vertical dielectric structure; forming a plate above and coupled to the leakers; and cutting the plate such that one of the leakers is electrically coupled to a top electrode formed for one of the two ferroelectric capacitors for a first memory cell and another one of the leakers is electrically coupled to a top electrode formed for another one of the two ferroelectric capacitors for a second memory cell.

An example method 11 of forming a memory device can include features of example method 12 of forming a memory device and can include forming the top electrode for the one of two ferroelectric capacitors on ferroelectric material for the one of two ferroelectric capacitors and on a top surface of the one of the leakers for the one of two ferroelectric capacitors, the top electrode extending from the top surface of the one of the leakers to a top surface of the top region of the vertical dielectric structure.

An example method 12 of forming a memory device can include features of any of the preceding example methods 10-11 of forming a memory device and can include, for each of the two ferroelectric capacitors, forming a metallic layer on the ferroelectric material opposite the leaker, with a top surface of the metallic layer at a vertical level of the top surface of the leaker and the top surface of the ferroelectric material; and forming the top electrode on the metallic layer, on the top surface of the ferroelectric material, and on the top surface of the leaker, the top electrode extending from the top surface of the leaker to a top surface of the top region of the vertical dielectric structure.

An example method 13 of forming a memory device can include features of any of the preceding example methods 10-12 of forming a memory device and can include, for each of the two ferroelectric capacitors, forming the top electrode on the ferroelectric material such that a top surface of the top electrode is at a vertical level of the top surface of the leaker and the top surface of the ferroelectric material; and forming the plate, prior to cutting the plate, on the top surface of the top electrode, the top surface of the leaker, and the top surface of the ferroelectric material, with the plate extending above a top surface of the top region of the vertical dielectric structure.

An example method 14 of forming a memory device can include features of any of the preceding example methods 10-13 of forming a memory device and can include forming the vertical dielectric structure with the top region to include a silicon nitride and the bottom region including an oxide.

An example method 15 of forming a memory device can include features of example method 15 of forming a memory device and any of the preceding example methods 10-14 of forming a memory device and can include cutting the plate to include forming an opening above the silicon nitride.

In an example method 16 of forming a memory device, any of the example methods 10 to 15 of forming a memory device may be performed in forming an electronic apparatus further comprising a host processor and a communication bus extending between the host processor and the memory device.

In an example method 17 of forming a memory device, any of the example methods 10 to 16 of forming a memory device may be modified to include operations set forth in any other of example methods 10 to 16 of forming a memory device.

In an example method 18 of forming a memory device, any of the example methods 10 to 17 of forming a memory device may be implemented at least in part through use of instructions stored as a physical state in one or more machine-readable storage devices.

An example method 19 of forming a memory device can include features of any of the preceding example methods 10 to 18 of forming a memory device and can include performing functions associated with any features of example memory devices 1 to 13.

An example method 20 of forming a memory device can comprise forming a vertical dielectric structure having a top region on a bottom region; forming a first bottom electrode for a first ferroelectric capacitor on a first side of the vertical dielectric structure, the first bottom electrode extending from a top of a first transistor to a first position below the top region of the vertical dielectric structure; forming a second bottom electrode for a second ferroelectric capacitor on a second side of the vertical dielectric structure opposite the first side, the second bottom electrode extending from a top of a second transistor to a second position below the top region of the vertical dielectric structure; forming a first leaker on the first bottom electrode and on the first side of the vertical dielectric structure above the first bottom electrode; forming a second leaker on the second bottom electrode and on the second side of the vertical dielectric structure above the second bottom electrode; forming ferroelectric material covering the top region of the vertical dielectric structure, the first leaker, and the second leaker; removing portions of the ferroelectric material, the first leaker, and the second leaker such that a top surface of the first leaker and a top of ferroelectric material adjacent and contacting the first leaker are formed and exposed below the top region of the vertical dielectric structure and such that a top surface of the second leaker and a top of ferroelectric material adjacent and contacting the second leaker are formed and exposed below the top region of the vertical dielectric structure; forming a plate above and coupled to the first leaker and the second leaker; and cutting the plate such that the first leaker is electrically coupled to a top electrode formed for the first ferroelectric capacitor of a first memory cell and the second leaker is electrically coupled to a top electrode formed for the second ferroelectric capacitor of a second memory cell.

In an example method 21 of forming a memory device, any of example method 20 of forming a memory device may be performed in forming an electronic apparatus further comprising a host processor and a communication bus extending between the host processor and the memory device.

In an example method 22 of forming a memory device, any of the example methods 20 to 21 of forming a memory device may be modified to include operations set forth in any other of example methods 20 to 21 of forming a memory device.

In an example method 23 of forming a memory device, any of the example methods 20 to 22 of forming a memory device may be implemented at least in part through use of instructions stored as a physical state in one or more machine-readable storage devices.

An example method 24 of forming a memory device can include features of any of the preceding example methods 20 to 23 of forming a memory device and can include performing functions associated with any features of example memory devices 1 to 13.

An example method 1 of forming a memory cell can comprise forming a dielectric structure; forming an electrode along a first portion of a side of the dielectric structure; forming a leaker material along a second portion of the side of the dielectric structure and along a side of the first electrode; forming ferroelectric material along a side of the leaker material and over a top surface of the dielectric structure; removing a portion of the ferroelectric material such that the ferroelectric material is below the top surface of the dielectric structure and a portion of the leaker material is exposed; and forming conductive material in contact with the exposed portion of the leaker material.

An example method 2 of forming a memory cell can include features of example method 1 of forming a memory cell and can include forming the dielectric structure comprising: forming an oxide structure; and forming a nitride structure over the oxide structure.

An example method 3 of forming a memory cell can include features of any of the preceding example methods 1-2 of forming a memory cell and can include further comprising forming a resist material over the ferroelectric material, and wherein removing a portion of the ferroelectric material comprises etching back a portion of the resist material and the portion of the ferroelectric material.

An example method 4 of forming a memory cell can include features of example method 3 of forming a memory cell and any of the preceding example methods 1-2 of forming a memory cell and can include further comprising etching back a portion of the leaker material.

An example method 5 of forming a memory cell can include features of example method 3 of forming a memory cell and any of the preceding example methods 1-2 and 4 of forming a memory cell and can include further comprising removing a remaining portion of the resist material.

An example method 6 of forming a memory cell can include features of example method 5 of forming a memory cell and any of the preceding example methods 1-4 of forming a memory cell and can include forming conductive material in contact with the exposed portion of the leaker material comprises forming top electrode material in contact with the exposed portion of the leaker material after removing the remaining portion of the resist material.

An example method 7 of forming a memory cell can include features of example method 6 of forming a memory cell and any of the preceding example methods 1-5 of forming a memory cell and can include further comprising: planarizing the top electrode material; forming plate material over the top electrode material; and cutting the plate material.

An example method 8 of forming a memory cell can include features of any of the preceding example methods 1-7 of forming a memory cell and can include further comprising: forming a metallic material over the ferroelectric material; and forming a resist material over the metallic material, and wherein removing a portion of the ferroelectric material comprises etching back a portion of the resist material, a portion of the metallic material and the portion of the ferroelectric material.

An example method 9 of forming a memory cell can include features of any of the preceding example methods 1-8 of forming a memory cell and can include further comprising, after forming the ferroelectric material along the side of the leaker material and over the top surface of the dielectric structure, forming a top electrode material over the ferroelectric material; wherein removing a portion of the ferroelectric material comprises: etching back the portion of the ferroelectric material; and etching back a portion of the top electrode material; and wherein forming conductive material in contact with the exposed portion of the leaker material comprises forming plate material in contact with the exposed portion of the leaker material.

An example method 10 of forming a memory cell can include features of example method 9 of forming a memory cell and any of the preceding example methods 1-8 of forming a memory cell and can include further comprising cutting the plate material.

In an example method 11 of forming a memory cell, any of the example methods 1 to 10 of forming a memory cell may be performed in forming an electronic apparatus further comprising a host processor and a communication bus extending between the host processor and a memory device containing the memory cell.

In an example method 12 of forming a memory cell, any of the example methods 1 to 11 of forming a memory cell may be modified to include operations set forth in any other of example methods 1 to 11 of forming a memory cell. In an example method 13 of forming a memory cell, any of the example methods 1 to 12 of forming a memory cell may be implemented at least in part through use of instructions stored as a physical state in one or more machine-readable storage devices.

An example method 14 of forming a memory cell can include features of any of the preceding example methods 1 to 13 of forming a memory cell and can include performing functions associated with any features of example memory devices 1 to 13.

An example machine-readable storage device storing instructions, that when executed by one or more processors, cause a machine to perform operations, can comprise instructions to perform functions associated with any features of example memory devices 1 to 13, perform methods associated with any features of example methods 1 to 24 of forming a memory device, or perform methods associated with any features of example methods 1 to 14 of forming a memory cell.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells, each memory cell including a ferroelectric capacitor, each ferroelectric capacitor having a bottom electrode, a top electrode, ferroelectric material, and a leaker electrically coupling the bottom electrode to the top electrode; and
plates contacting the memory cells, each plate on and contacting a different set of the memory cells, the plates separated from each other along a direction parallel to an access line to the array, without dummy memory cells between the different sets of memory cells.

2. The memory device of claim 1, wherein the top electrode contacts the leaker on a top surface of the leaker, the top electrode and the leaker being directly adjacent a dielectric surface, with a plate on and contacting the top electrode.

3. The memory device of claim 1, wherein:
the top electrode contacts the leaker on a top surface of the leaker, the top electrode and the leaker directly adjacent a dielectric surface;
a plate is on and contacting the top electrode;
the leaker has a length extending from the top surface of the leaker downward, the leaker separated from a second top electrode along the length by the ferroelectric material of the ferroelectric capacitor; and
the second top electrode is positioned between the ferroelectric material and the top electrode of the ferroelectric capacitor.

4. The memory device of claim 1, wherein a plate contacts the leaker on a top surface of the leaker, the plate and the leaker being directly adjacent a dielectric surface, the plate on and contacting the top electrode, with the leaker separated from the top electrode by ferroelectric material of the ferroelectric capacitor and coupled to the top electrode by the plate.

5. The memory device of claim 4, wherein a portion of the plate extends vertically above and offset from a top surface of the dielectric surface, the top surface of the dielectric surface being at a level of a top surface of a lower portion of the plate.

6. The memory device of claim 1, wherein electrode material of the top electrode or the bottom electrode includes one or more of titanium, titanium nitride, or tungsten nitride.

7. The memory device of claim 1, wherein ferroelectric material of the ferroelectric capacitor includes hafnium oxide, zirconium oxide, or a combination of hafnium oxide and zirconium oxide.

8. The memory device of claim 1, wherein each memory cell includes a transistor coupled to the bottom electrode, with the ferroelectric capacitor of the memory cell extending vertically from the transistor.

9. The memory device of claim 8, wherein the transistor includes a thin film transistor.

10. A method of forming a memory cell, the method comprising:
forming a dielectric structure;
forming an electrode along a first portion of a side of the dielectric structure;
forming a leaker material along a second portion of the side of the dielectric structure and along a side of the first electrode;
forming ferroelectric material along a side of the leaker material and over a top surface of the dielectric structure;
removing a portion of the ferroelectric material such that the ferroelectric material is below the top surface of the dielectric structure and a portion of the leaker material is exposed; and
forming conductive material in contact with the exposed portion of the leaker material.

11. The method of claim 10, wherein forming the dielectric structure comprises:
forming an oxide structure; and
forming a nitride structure over the oxide structure.

12. The method of claim 10, further comprising forming a resist material over the ferroelectric material, and wherein removing a portion of the ferroelectric material comprises etching back a portion of the resist material and the portion of the ferroelectric material.

13. The method of claim 12, further comprising etching back a portion of the leaker material.

14. The method of claim 12, further comprising removing a remaining portion of the resist material.

15. The method of claim 14, wherein forming conductive material in contact with the exposed portion of the leaker material comprises forming top electrode material in contact with the exposed portion of the leaker material after removing the remaining portion of the resist material.

16. The method of claim 15, further comprising:
planarizing the top electrode material;
forming plate material over the top electrode material; and
cutting the plate material.

17. The method of claim 10, further comprising:
forming a metallic material over the ferroelectric material; and
forming a resist material over the metallic material, and wherein removing a portion of the ferroelectric material comprises etching back a portion of the resist material, a portion of the metallic material and the portion of the ferroelectric material.

18. The method of claim 10, further comprising, after forming the ferroelectric material along the side of the leaker material and over the top surface of the dielectric structure, forming a top electrode material over the ferroelectric material;
wherein removing a portion of the ferroelectric material comprises:
etching back the portion of the ferroelectric material; and
etching back a portion of the top electrode material; and
wherein forming conductive material in contact with the exposed portion of the leaker material comprises forming plate material in contact with the exposed portion of the leaker material.

19. The method of claim 18, further comprising cutting the plate material.

20. A method of forming a memory device, the method comprising:
forming an array of memory cells, each memory cell including a ferroelectric capacitor, each ferroelectric capacitor having a bottom electrode, a top electrode, ferroelectric material, and a leaker electrically coupling the bottom electrode to the top electrode; and
forming plates contacting the memory cells, each plate on and contacting a different set of the memory cells, the plates separated from each other along a direction parallel to an access line to the array, without dummy memory cells between the different sets of memory cells.

21. The method of claim 20, wherein the method includes:
forming the bottom electrode and the leaker directly on an adjacent dielectric structure below a top region of the dielectric structure with the leaker on and extending from a top surface of the bottom electrode along the dielectric structure;
forming the ferroelectric material on a vertical side of the leaker;
forming the top electrode contacting the leaker on a top surface of the leaker, below the top region of the dielectric structure; and
forming a plate on and contacting the top electrode.

22. The method of claim 20, wherein the method includes:
forming the bottom electrode and the leaker directly on an adjacent dielectric structure below a top region of the dielectric structure with the leaker on and extending from a top surface of the bottom electrode along the dielectric structure, the leaker having a length extending from the top surface of the leaker downward;
forming the ferroelectric material on a vertical side of the leaker;
forming a second top electrode on the ferroelectric material opposite the leaker along a portion of the length of the leaker;
forming the top electrode contacting the leaker on a top surface of the leaker and positioned on and contacting the second top electrode; and
forming a plate on and contacting the top electrode.

23. The method of claim 20, wherein the method includes:
forming the bottom electrode and the leaker directly on an adjacent dielectric structure below a top region of the dielectric structure with the leaker on and extending from a top surface of the bottom electrode along the dielectric structure, the leaker having a length extending from the top surface of the leaker downward, the leaker having a top surface;
forming the ferroelectric material on a vertical side of the leaker;
forming the top electrode on the ferroelectric material opposite the leaker along a portion of the length of the leaker such that a top surface of the top electrode is at a vertical level of the top surface of the leaker and separated from the top surface of the leaker by a top surface of the ferroelectric material; and
forming a plate on and contacting the top surface of the leaker, the top surface of the ferroelectric material, and the top surface of the top electrode, the plate extending from below the top region of the dielectric structure to above the top region of the dielectric structure.

24. The method of claim 20, wherein forming plates separated from each other along a direction parallel to an access line to the array includes forming a common plate and cutting the common plate above a dielectric structure having a ferroelectric capacitor of a memory cell on one side of the dielectric structure and another ferroelectric capacitor of another memory cell of an opposite side of the dielectric structure.

25. A method of forming a memory device, the method comprising:
forming leakers on bottom electrodes on opposite sides of a vertical dielectric structure and on the sides of the vertical dielectric structure above the bottom electrodes for two ferroelectric capacitors, the vertical dielectric structure having a top region on a bottom region;
forming ferroelectric material covering the top region of the vertical dielectric structure and the leakers;
removing portions of the ferroelectric material such that top surfaces of the ferroelectric material adjacent and contacting the leakers are formed and exposed below the top region of the vertical dielectric structure;
forming a plate above and coupled to the leakers; and
cutting the plate such that one of the leakers is electrically coupled to a top electrode formed for one of the two ferroelectric capacitors for a first memory cell and another one of the leakers is electrically coupled to a top electrode formed for another one of the two ferroelectric capacitors for a second memory cell.

26. The method of claim 25, wherein the method includes forming the top electrode for the one of two ferroelectric capacitors on ferroelectric material for the one of two ferroelectric capacitors and on a top surface of the one of the leakers for the one of two ferroelectric capacitors, the top electrode extending from the top surface of the one of the leakers to a top surface of the top region of the vertical dielectric structure.

27. The method of claim 25, wherein the method includes, for each of the two ferroelectric capacitors:
forming a metallic layer on the ferroelectric material opposite the leaker, with a top surface of the metallic layer at a vertical level of the top surface of the leaker and the top surface of the ferroelectric material; and
forming the top electrode on the metallic layer, on the top surface of the ferroelectric material, and on the top surface of the leaker, the top electrode extending from the top surface of the leaker to a top surface of the top region of the vertical dielectric structure.

28. The method of claim 25, wherein the method includes, for each of the two ferroelectric capacitors:
forming the top electrode on the ferroelectric material such that a top surface of the top electrode is at a vertical level of the top surface of the leaker and the top surface of the ferroelectric material; and
forming the plate, prior to cutting the plate, on the top surface of the top electrode, the top surface of the leaker, and the top surface of the ferroelectric material, with the plate extending above a top surface of the top region of the vertical dielectric structure.

29. The method of claim 25, wherein the method includes forming the vertical dielectric structure with the top region including a silicon nitride and the bottom region including an oxide.

30. The method of claim 29, wherein cutting the plate includes forming an opening above the silicon nitride.
